(19) United States
(12) Patent Application Publication
(10) Pub. No.: US 2006/0097257 A1
(43) Pub. Date: May 11, 2006

(54) Method of forming electrode for plasma display panel

(75) Inventors: Kazuo Suzuki, Kawasaki (JP); Naoto Yanagihara, Kawasaki (JP); Yasuhiko Ishihara, Kawasaki (JP); Tetsurou Kawakita, Kawasaki (JP); Syuuma Eifuku, Kawasaki (JP)

Correspondence Address: STAAS & HALSEY LLP, SUITE 700, 1201 NEW YORK AVENUE, N.W., WASHINGTON, DC, 20005, US

(73) Assignee: Fujitsu Hitachi Plasma Display Limited, Kawasaki (JP)

(21) Appl. No.: 11/262,935

(22) Filed: Nov. 1, 2005

(30) Foreign Application Priority Data
Nov. 8, 2004 (JP) 2004-323627

(51) Int. Cl. H01L 29/04

(52) U.S. Cl. 257/59

(57) ABSTRACT

A method of forming an electrode for a plasma display panel, in which the method includes the steps of forming a first metal film on a second metal film after formation of the second metal film on a substrate, forming a resist pattern on the laminated metal films, and etching the laminated metal films with an etching solution, thereby forming an electrode of the laminated films. A first metal is different from a second metal, and the first metal and the second metal have properties such that the surface potential of the first metal decreases when the first metal and the second metal in the state of being soaked in an etching solution of the first metal are short-circuited. During or after the formation of the first metal film, a diffusion step is performed in which an atmospheric temperature is kept at such a temperature that the metal atoms of the second metal film diffuse in and on the surface of the first metal film.

### CROSS-REFERENCE TO RELATED APPLICATION

This application is related to Japanese Patent Application No.2004-323627 filed on Nov. 8, 2004, on the basis of which priority is claimed under 35 USC §119, the disclosure of this application being incorporated by reference in its entirety.

### BACKGROUND OF THE INVENTION

1. Field of the Invention

The present invention relates to a method of forming an electrode for a plasma display panel (hereinafter referred to as “PDP”), and more specifically relates to a method of forming an electrode for a plasma display panel, by which an electrode of laminated films is formed on a substrate of the PDP.

2. Description of the Related Art

In the case of forming an electrode on a substrate of a PDP, especially an AC-type PDP having a three-electrode surface discharge structure, laminated films having a three-layered structure of Cr/Cu/Cr are often used as an electrode wiring material. The laminated films are called a first layer Cr, a second layer Cu, and a third layer Cr in order from the substrate side.

Each of the layers is a necessity in the laminated films, as the first layer Cr serves to secure adhesiveness to the substrate, the second layer Cu serves to lower electric resistance as much as possible, and the third layer Cr serves to prevent oxidation of the second layer Cu. The laminated films are sequentially formed on a substrate material by vacuum processing, such as sputtering or vacuum evaporation.

Subsequently, using a photosensitive resist, an electrode resist pattern is formed on the top face of the laminated films, and the laminated films are etched with an appropriate chemical under appropriate process conditions, to form an electrode.

In the AC-type PDP, a dielectric layer made of low melting point glass is normally formed on the electrode of the laminated films. A method of forming the dielectric layer is as follows. First, an organic resin material, added with a glass powder as a material for the dielectric layer, is printed using, for example, a screening plate, or is formed into a sheet shape to be attached, so as to cover the surface of the electrode. Thereafter, the organic resin material is heated to a prescribed temperature to be burned and removed, and the glass powder is further burned, so as to obtain the dielectric layer.

The above mentioned AC-type PDP having the three-layered electrode structure of Cr/Cu/Cr is disclosed in Japanese Patent Application Laid-Open No. 2000-348626.

In the foregoing formation of the electrode of the laminated films, the surface of the third layer Cr is covered with an oxidized film (hereinafter referred to as passivation film) at the time when the laminated films are formed. In etching, therefore, it is not possible to etch the metal Cr inside the third layer Cr unless the passivation film is removed with a treatment chemical.

However, since this passivation film is very stable chemically, the film is difficult to remove even when being subjected to a prescribed etching treatment, resulting in difficulty in etching of the metal Cr inside the third layer Cr.

Therefore, when etching is performed in a state where the surface of the third layer Cr is covered with the passivation film, the cross section of the etched electrode is in an eaves shape where the third layer Cr overhangs more than the second layer Cu. This makes the dielectric material resistant to entering into the sides of the electrode in the formation of the dielectric layer on the etched electrode.

For this reason, when a display is made after production of the PDP, discharge is concentrated on the above-described place containing no dielectric material in discharging between the electrodes, which causes an excessive current (arc current) to flow in the electrode, leading to discontinuity of the electrode wiring. With the electrode wiring disconnected, the entire one line of the electrode which has a disconnected place becomes incapable for display, resulting in significant deterioration in quality and reliability of the display.

### SUMMARY OF THE INVENTION

The present invention was made in consideration of the foregoing situation, and has an object to sufficiently fill the sides of an electrode with a dielectric material to prevent electrode discontinuity due to an arc current by diffusing an element of a metal film immediately under the top layer of laminated films in a metal film as the top layer to enable etching of the metal film as the top layer in a stable and effective manner so as to form an electrode in proper shape.

The present invention provides a method of forming an electrode for a plasma display panel having an electrode covered with a dielectric layer, the method comprising: forming a first metal film on a second metal film after formation of at least the second metal film on a substrate; forming a resist pattern for electrode formation on the top face of the laminated first and second metal films; and etching the laminated first and second metal films with an etching solution, thereby forming an electrode of the laminated films, wherein a first metal constituting the first metal film is different from a second metal constituting the second metal film, the first metal and the second metal having properties such that the surface potential of the first metal decreases when the first metal and the second metal in the state of being soaked in an etching solution of the first metal are short-circuited, and during or after the formation of the first metal film, a diffusion step is performed in which an atmospheric temperature is kept at such a temperature that the metal atoms of the second metal film diffuse in and on the surface of the first metal film.

According to the present invention, since the metal atoms of the second metal layer are diffused in and on the surface of the first metal layer as the top layer, in etching treatment, the surface potential of the first metal film becomes lower than in the case where the metal atoms of the second metal layer are not diffused in the first metal layer, thereby facilitating elution of the passivation film, formed on the surface of the first metal layer, into an etching solution. This results in etching of the first metal film in a stable and effective manner to form the electrode in proper shape, thereby preventing formation of a void of the dielectric material on the sides of the electrode so as to prevent electrode discontinuity due to an arc current.

### BRIEF DESCRIPTION OF THE DRAWINGS

FIGS. 1(a) and 1(b) are a whole view and a partially exploded oblique view showing a configuration of a PDP to which the present invention is applied.

FIGS. 2(a) to 2(g) are explanatory views showing one example in an electrode formation method of the present invention.

FIG. 3 is an explanatory view showing a configuration of a current-potential measurement device used in the embodiment of the present invention.

FIGS. 4(a) and 4(b) are graph showings a result of measurement using the current-potential measurement device in the embodiment of the present invention.

FIG. 5 is a graph showing a result of measurement in an example of the present invention.

FIG. 6 is a graph showing a result of measurement in a comparative example.

### DESCRIPTION OF THE PREFERRED EMBODIMENTS

In the present invention, examples of the substrate include substrates respectively made of glass, quartz, ceramic and the like, and substrates obtained by forming on the above-mentioned substrates a requested constituent, such as an electrode, an insulating film, a dielectric layer and a protective film.

The laminated metal films may be obtained by forming at least the second metal film and then forming the first metal film on the second metal layer. Hence any kind of metal films may be laminated in any number under the second metal film. However, it is desirable that the electrode formation method further comprise a step of forming a third metal film under the second metal film before the formation of the second metal film, and that a third metal constituting the third metal film is the same metal as the first metal constituting the first metal film.

It is desirable that the second metal film and the first metal film are formed by vacuum processing, such as sputtering or vacuum evaporation.

After the lamination of the metal films, a resist pattern for electrode formation is formed on the top face of the laminated metal films. The photolithograph technique well known in the field can be applied to this formation of the resist pattern for electrode formation.

Next, the laminated metal films are etched with an etching solution to form an electrode of the laminated film. The etching solution used at this time is desirably an acidic aqueous solution such as hydrochloric acid. This is because a resist is normally developed with an alkaline cleaning liquid and thus the use of an alkaline etching solution may cause the resist to peel off.

In the present invention, the first metal constituting the first metal film needs to be different from the second metal constituting the second metal film. Further, metals, having properties such that the surface potential of the first metal decreases when the first metal and the second metal in the state of being soaked in the etching solution for the first metal are short-circuited, are used as the first metal and the second metal.

Examples of the first metal having such properties may include Cr (chrome), Ti (titanium), V (vanadium), Ni (nickel), W (tungsten), and alloys of these metals. The first metal serves to cover the second metal so as to prevent oxidation of the second metal. As this first metal used is a metal on the surface of which a stable passivation film is formed.

Examples of the second metal may include Au (gold), Ag (silver), Cu (copper), Al (aluminum), and alloys of these metals. As this second metal used is a low resistive material commonly used as a high conductive material for wiring.

In the present invention, the electrode formation method comprises a diffusion step in which an atmospheric temperature is kept at such a temperature that the metal atoms of the second metal film diffuse in and on the surface of the first metal film during or after the formation of the first metal film.

For example when the substrate is put into an vacuum chamber, followed by formation of the second metal film by vacuum processing such as sputtering or vacuum evaporation and formation of the first metal film on the second metal film, “during the formation of the first metal film” means a period from completion of the formation of the second metal film to completion of the formation of first metal film. In this case, it is desirable to perform the process in the diffusion step by keeping the temperature in the vacuum chamber at 150° C. or higher, and more preferably 200° C. or higher, during the formation of the first metal film.

For example when the substrate is put into the vacuum chamber, followed by formation of the second metal film by vacuum processing such as sputtering or vacuum evaporation and formation of the first metal film, “after the formation of the first metal film” means a state in which the substrate remains held in the vacuum chamber after the formation of the first metal film. In this case, it is desirable to perform the process in the diffusion step by keeping the temperature in the vacuum chamber at 150° C. or higher, and more preferably 200° C. or higher, after the formation of the first metal film. The time period for keeping the temperature in the vacuum chamber is desirably in the range of about 2 to 15 minutes.

As described above, the temperature kept in the diffusion step is 150° C. or higher, and more preferably 200° C. or higher. When the temperature is 150° C. or lower, diffusion might not be sufficiently taken place. Although diffusion may take place even at a considerably high temperature, e.g. 300° C. or higher, a typical film formation device to carry out vacuum processing is not designed to keep a film formation temperature as high as above described. It is therefore desirable to keep the temperature at about 300° C. or lower in the case of considering the cost for the film formation device.

In order to prevent, to the utmost, further oxidation of the outermost surface of the first metal film due to the process atmosphere, the diffusion step is desirably carried out either under reduced pressure close to vacuum or in a reducing atmosphere such as H₂, N₂ or Ar.

With this diffusion step carried out, the metal atoms of the second metal film diffuse in and on the surface of the first metal film. When Cu is used as the second metal while Cr is used as the first metal, for example, Cu diffuses in the Cr grain boundary and on the Cr surface. The reason for such diffusion is as follows.

Generally, atoms align more irregularly in the deeper inside of a grain boundary of polycrystal, and the atoms easily move while diffusing. Especially, the surface portion is a “specific grain boundary” where diffusion tends to occur more than in the grain boundary. Accordingly, the atoms constituting the lower layer film (second metal film) diffuse while passing mainly through the grain boundary of the upper layer film (first metal film) as a passage, and consequently exist in volume on the surface of the upper layer film.

A “diffusion coefficient D” to show a diffusion capacity of atoms shows dependency on a temperature as shown by the following expression (1).
D∝exp (−ΔG*/RT) (1)
where ΔG* is an active energy required for occurrence of diffusion, R is a gas constant, and T is an absolute temperature.

The expression (1) shows that atoms are remarkably apt to diffuse when the temperature is a certain temperature or higher as the temperature becomes capable of exceeding the active energy in the expression. Since ΔG* in the grain boundary and on the surface as described above are small as compared with the inside, the diffusion tends to occur at a relatively lower temperature.

The electrode of the laminated films may have a three-layered structure of a first layer of Cr, a second layer of Cu and a third layer of Cr in order from the substrate side. When the electrode has such a three-layered structure, the metal atoms of the second layer Cu are diffused in and on the surface of the third layer Cr in the diffusion step.

In the above-mentioned configuration, the diffusion step may be a step in which the atmospheric temperature is kept at such a temperature that the metal atoms of the second layer Cu diffuse in and on the surface of the third layer Cr during a period from completion of the formation of the second layer Cu to completion of the formation of the third layer Cr. Further, the diffusion step may be a step in which the atmospheric temperature is kept at such a temperature that the metal atoms of the second layer Cu diffuse in and on the surface of the third layer Cr for a prescribed period of time after the formation of the third layer Cr.

In the following, the present invention is specifically described based upon embodiments shown in drawings. It should be noted that the present invention is not limited to the following description, and a variety of modifications are possible.

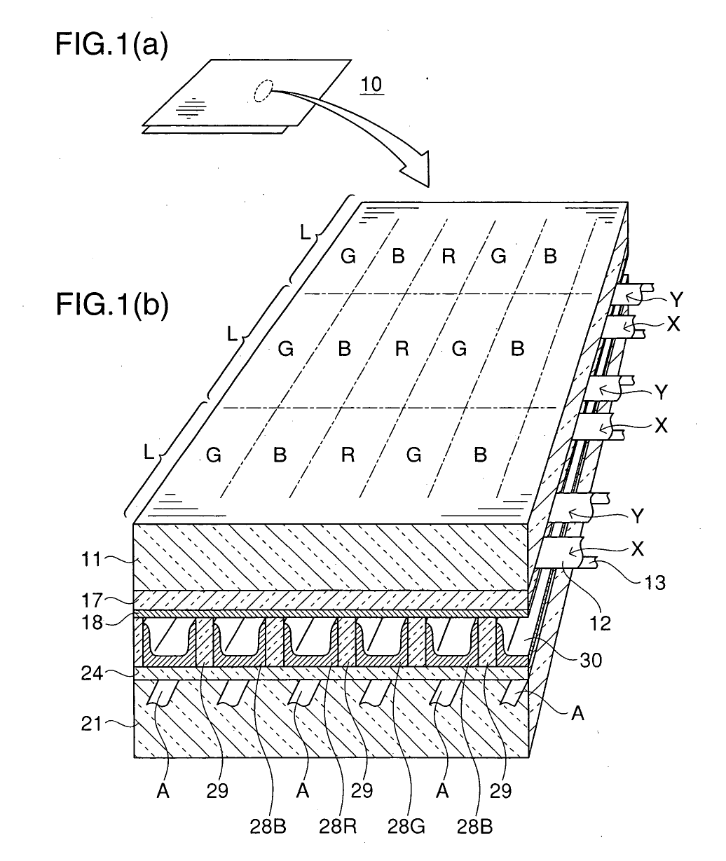

FIGS. 1 (a) and 1 (b) are a whole view and a partially exploded perspective view showing a configuration of a PDP to which the electrode formation method of the present invention is applied. This PDP is an AC-type PDP having a three-electrode surface discharge structure for color display.

This PDP is constituted of a front-side panel assembly including a front-side substrate 11, and a rear-side panel assembly including a rear-side substrate 21. Although the front-side substrate 11 and the rear-side substrate 21 are both a glass substrate, other than the glass substrate, a quartz substrate, a ceramic substrate or the like can also be used.

On the inner face of the front-side substrate 11, a pair of display electrodes X and Y are formed in parallel at intervals such that discharge will not occur between the electrodes X and Y. The space between the display electrodes X and Y is a display line L. Each of the display electrodes X and Y is constituted of a wide transparent electrode 12 of ITO, SnO₂ or the like, and a narrow bus electrode 13 made of a metal, for example, Ag, Au, Al, Cu, Cr or a lamination body of those metals (e.g. laminated films of Cr/Cu/Cr). The display electrodes X and Y can be formed in requested number, thickness and width at requested intervals by using a thick film formation technique such as screen printing for Ag and Au, and using a thin film formation technique such as evaporation and sputtering, and an etching technique for other metals.

A dielectric layer 17 for driving an alternate current (AC) is formed on the display electrodes X and Y so as to cover the display electrodes X and Y. A low melting point glass paste is applied onto the front-side substrate 11 by screen printing, which is then burned so as to form the dielectric layer 17.

On the dielectric layer 17 formed is a protective film 18 for protecting the dielectric layer 17 from damage due to ion collision caused by discharge at the time of display. This protective film is made of, for example, MgO, CaO, SrO, BaO or the like.

On the inner face of the rear-side substrate 21, a plurality of address electrodes A are formed in the direction across a pair of display electrodes X and Y in a planar view, and a dielectric layer 24 is formed covering the address electrodes A. The address electrode A serves to generate address discharge for selecting a light-emitting cell at an intersection with the electrode Y, and has a three-layered structure of Cr/Cu/Cr. The address electrode A may also be formed of, for example, Ag, Au, Al, Cu, Cr or the like. As in the case of the display electrodes X and Y, the address electrodes A can be formed in requested number, thickness and width at requested intervals by using the thick film formation technique such as screen printing for Ag and Au, and using the thin film formation technique such as evaporation and sputtering, and the etching technique for other metals. The dielectric layer 24 can be formed using the same material as well as the same method as those of the dielectric layer 17.

A plurality of barrier ribs 29 are formed between the adjacent address electrodes A on the dielectric layer 24. The barrier ribs 29 can be formed by sandblasting, printing, photo-etching, or the like. For example, in sandblasting, a glass paste comprising a low melting point glass flit, a binder resin, a solvent and the like is applied onto the dielectric layer 24, followed by drying, and in a state where 0a cutting mask having openings with a pattern of barrier ribs is provided on the obtained glass paste layer, glass particles are sprayed onto the glass paste layer. The glass paste layer exposed to the openings of the mask is cut and further burned so that the barrier ribs 29 are formed. Moreover, in photo-etching, in place of cutting with the cutting particles, a photosensitive resin is used as a binder resin. After exposure and development using the mask, the film is burned so that the barrier rib 29 is formed.

On the side faces of the barrier ribs 29 as well as portions on the dielectric layer 24 between the barrier ribs, fluorescent layers 28R, 28G and 28B respectively colored with red (R), green (G) and blue (B) are formed. A fluorescent paste containing a fluorescent powder, a binder resin, and a solvent is applied into discharge spaces in the shape of a recessed groove between the barrier ribs 29 by screen printing, a method with use of a dispenser, or the like. This application is repeated for each color, followed by burning, to form the fluorescent layers 28R, 28G and 28B. These fluorescent layers 28R, 28G and 28B can also be formed by the photolithography technique, using a sheet-like fluorescent layer material (i.e. green sheet) that contains a fluorescent powder, a photosensitive material, and a binder resin. In this case, a sheet with a requested color is applied onto the entire face of the display region on the substrate, which is then exposed and developed. This operation is repeated for each color so that a fluorescent layer with each color can be formed between the corresponding barrier ribs.

The PDP is produced in the following manner. The panel assembly on the front side and the panel assembly on the rear side are oppositely arranged such that the display electrodes X and Y intersect with the address electrodes A, the periphery is sealed, and discharge spaces 30 surrounded by the barrier ribs 29 are filled with a discharge gas. In this PDP, the discharge space 30 as an intersecting portion where the display electrodes X and Y intersect with the address electrode A is a cell region (unit light-emitting region) as the minimum unit for display. One pixel is composed of three cells of R, G and B.

The electrode formation method of the present invention is an electrode formation method for forming the bus electrodes 13 of the display electrodes X and Y and the address electrode A in the AC-type PDP having a three-electrode surface discharge structure, as described above. These bus electrodes 13 and the address electrode A are formed of the laminated films of the first layer Cr, the second layer Cu and the third layer Cr in order from the substrate side. In the following description, the bus electrodes 13 and the address electrode A of the laminated films are simply referred to as an electrode for the sake of simplification of the description.

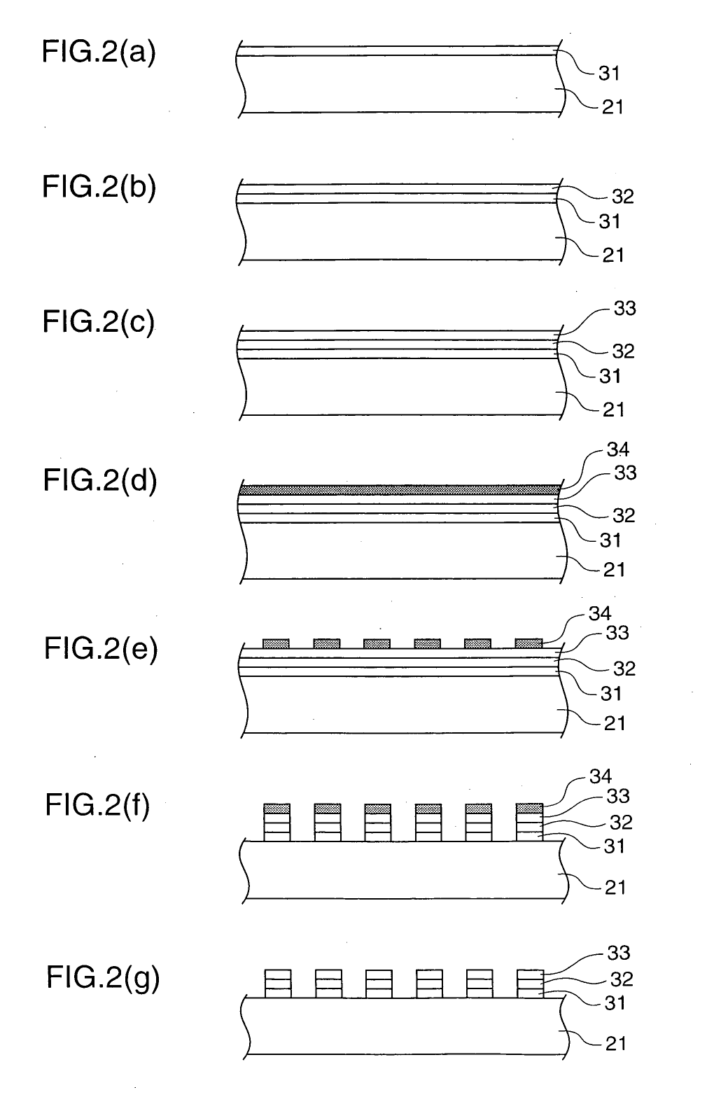

FIGS. 2(a) to 2(g) are explanatory views showing one example of the electrode formation method of the present invention. Here, a description is given, taking as an example a method for forming the address electrode A on the rear-side glass substrate 21.

First, a first layer Cr 31 is formed on the glass substrate 21 by vacuum processing such as sputtering or vacuum evaporation (cf. FIG. 2(a)) Next, a second layer Cu 32 is formed on the first layer Cr 31 (cf. FIG. 2(b)). Thereafter, a third layer Cr 33 is formed on the second layer Cu 32 while keeping the atmospheric temperature at 150° C. or higher, and more preferably 200° C. or higher (cf. FIG. 2(c)). This allows the metal atoms of the second layer Cu 32 to diffuse in and on the surface of the third layer Cr 33. This diffusion step may be performed in such a manner that the atmospheric temperature is kept at 150° C. or higher, and more preferably 200° C. or higher, after the formation of all the first layer Cr 31, the second layer Cu 32 and the third layer Cr 33.

The first layer Cr 31 is formed to have a thickness of the order of about 0.05 μm, the second layer Cu 32 is formed to have a thickness of the order of 1 to 3 μm, and the third layer Cr 33 is formed to have a thickness of the order of about 0.15 μm. The first layer Cr 31 has a thickness of the order of about 0.05 μm from the sense that it serves to secure adhesiveness to the glass substrate 21. The third layer Cu 33 has a thickness of the order of about 0.15 μm, which is larger than the thickness of the first layer Cr 31, since the third layer Cu 33 serves to protect the second layer Cu 32 from oxidation. Although it is described here that the second layer Cu 32 has a thickness of the order of 1 to 3 μm, the thickness is changed as appropriate according to a size of a flowing current.

Next, a resist 34 is formed on the third layer Cr 33 (cf. FIG. 2(d)), and thereafter the resist 34 is patterned to form an electrode resist pattern (cf. FIG. 2(e)).

Subsequently, the third layer Cr 33, the second layer Cu 32 and the first layer Cr 31 excluding the places thereon where the resist has been formed are removed with an etching solution (cf. FIG. 2(f)), and the resist 34 on the third layer Cr 33 is removed so that an electrode of the laminated films comprising the first layer Cr 31, the second layer Cu 32 and the third layer Cr 33 is formed (cf. FIG. 2(g)).

In forming this electrode of the laminated films, when the laminated films are formed, the surface of the third layer Cr is covered with a passivation film. The diffusion process is then performed to facilitate elution of the passivation film on the surface of the third layer Cr, into the etching solution.

The present inventors found that making Cu and Cr coexistent in and on the surface of the third layer Cr can facilitate etching of the third layer Cr. A verification method and mechanism for such findings are described below.

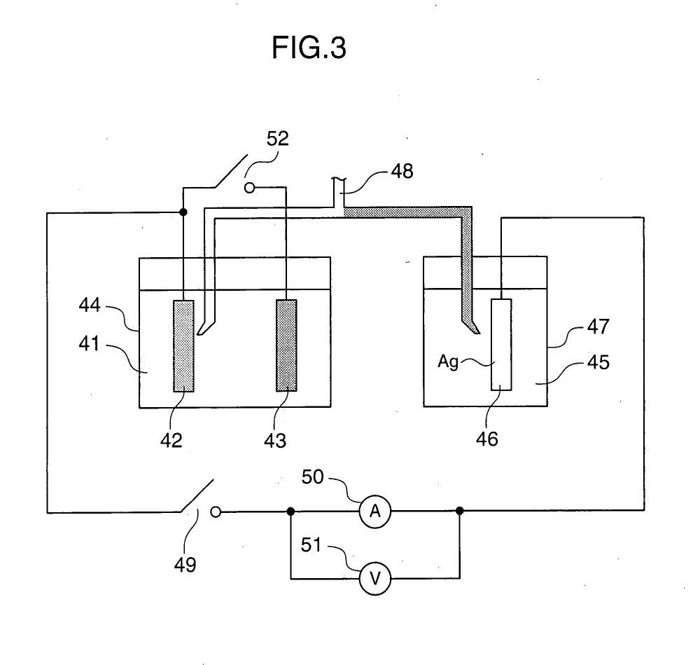

FIG. 3 is an explanatory view showing a configuration of a current-potential measurement device.

This device was used for study on how the etching proceeds due to coexistence of Cr and Cu, namely occurrence of electric short circuit of Cr and Cu.

In this device, a container 44, in which a Cr sample 42 and a Cu sample 43 are put in an etching solution 41 of Cr, and a container 47, in which an Ag electrode 46 is soaked in a saturated KCl aqueous solution 45, are connected using a salt bridge 48 obtained by mixing agar with AgCl. Hereinafter, the latter container 47 and the salt bridge 48 are generically called an Ag/AgCl reference electrode.

As the Cr sample 42 used was a Cr thin film (thickness: 200 nm) formed on a glass substrate using a target with a purity of 99.9%. As the Cu sample 43 used was a rolled plate made of oxygen-free copper with a purity of 99.9%.

In order to uniform the surface area involved in etching, a coating member not to be soaked in the etching solution was applied to the surface of each sample. However, only a region with a size of 1 cm×1 cm on the sample surface was not coated, and the sample surface was exposed to the etching solution.

The Cr sample 42, a switch 49 for circuit, an ammeter 50 and a voltmeter 51 were connected as shown in the figure. Further, a switch 52 for coupling was provided so as to electrically short-circuit the Cr sample 42 and the Cu sample 43.

In the case of using a photosensitive resist to be developed and peeled in an alkaline solution in formation of the electrode, an acid chemical needs to be used as an etching solution for Cr from the perspective of the resistance properties of the resist. Hence HCl (pH=0 to 1) was used as the etching solution 41 for the Cr sample 42.

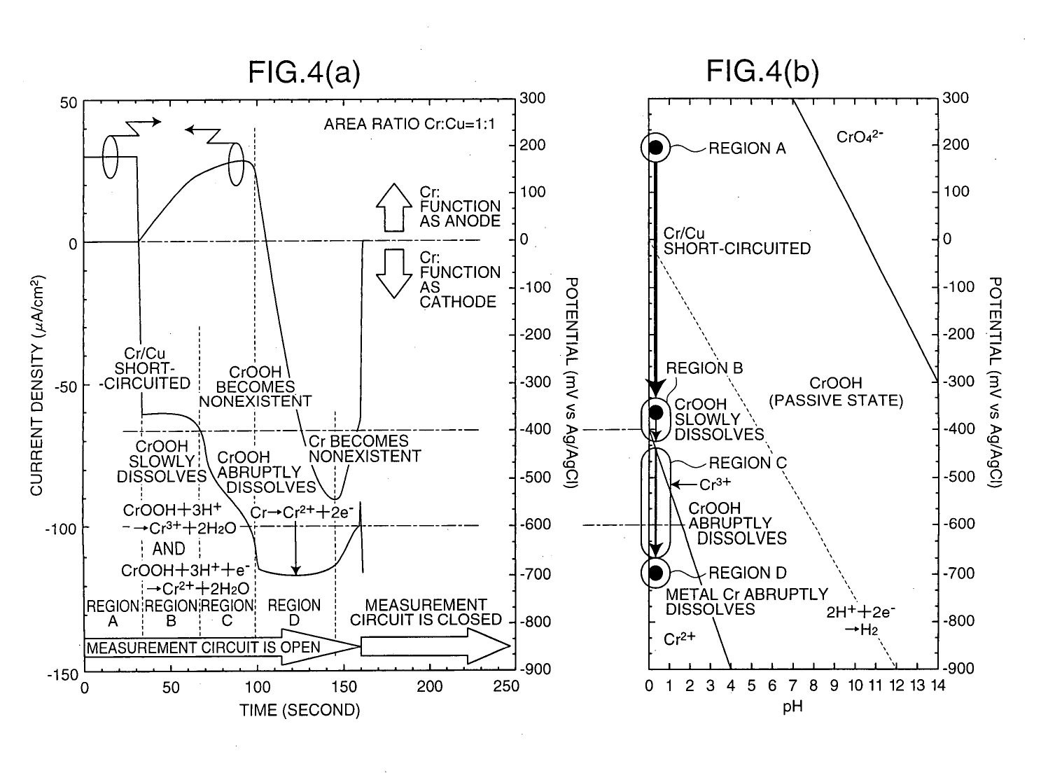

FIG. 4(a) and FIG. 4(b) are graphs showing a result of measurement using the current-potential measurement device.

In FIG. 4(a), soaking time is plotted as abscissa, a density of a current that flew in the circuit as left ordinate, and a surface potential of the Cr sample as right ordinate.

FIG. 4(b) is a potential-pH diagram (Pourbaix diagram) of Cr. In this diagram, a pH of a chemical in which Cr is soaked is plotted as abscissa and a Cr surface potential at that time is plotted as ordinate, graphically-showing a state of Cr in which Cr can exist in a chemically thermodynamically stable manner at each pH. The reference electrode is Ag/AgCl. It is found from this diagram that, for example when the Cr surface potential is +100 mV in the alkaline chemical at pH 13, CrO₄²⁻ is the most stable state of Cr, and CrO₄²⁻ is eluted as ions from the Cr surface.

Using the current-potential measurement device shown in FIG. 3, the Cr sample and the Cu sample were soaked in the etching solution, and each switch was conducted to measure behaviors of the current and voltage. The measurement results are described using FIG. 4(a) and FIG. 4(b).

First, when only the Cr sample was soaked in the etching solution and the switch for circuit is simultaneously conducted, the surface potential of the Cr sample was 200 mV and the current density was 0 μA/cm² (region A of FIG. 4(a)).

Next, when the Cu sample was soaked in the etching solution and the switch for coupling was simultaneously turned on, the surface potential of the Cr sample showed −360 mV and a current began to flow. For a while, the surface potential modestly changed in the range of −360 to −400 mV (region B of FIG. 4(a)). The surface potential was then began decreasing at about −400 mV and sharply decreased to −700 mV (region C of FIG. 4(a)).

Thereafter, the constant surface potential of −700 mV was shown until the Cr sample became nonexistent (region D of FIG. 4(a)).

Further, the current flowing direction reversed at the time of the shift from the region C to the region D.

The relation between the current-potential behaviors shown in FIG. 4(a) and the Pourbaix diagram of Cr shown in FIG. 4(b) is described below.

First, in the region A with a potential of +200 mV, as seen from FIG. 4(b), CrOOH (passivation film of Cr) is highly stable, and etching, i.e. elution of Cr. does not proceed and thus a current does not flow.

Next, when the Cr sample and the Cu sample are short-circuited, electrons are supplied from Cu to Cr. As a result, the surface potential of Cr decreases from −360 to −400 mV (region B). As seen from the Pourbaix diagram of Cr, with such a potential, CrOOH reacts with H⁺ according to the following expression (2) and Cr³⁺ elutes slowly.
CrOOH+3H⁺→Cr³⁺+2H₂O (2)

When the surface potential decreases with the elution of Cr³⁺ to reach −400 mV (boundary between the region B and the region C), as seen from the Pourbaix diagram of Cr, Cr³⁺ and Cr²⁺ become stable, and thereby CrOOH rapidly elutes according to the following expressions (3) and (4), and then becomes nonexistent (region C).
CrOOH+3H⁺→Cr³⁺+2H₂O (3)
CrOOH+3H⁺+e⁻→Cr²⁺+2H₂O (4)

At this time, the Cr sample functions as an anode as it receives electrons from Cu sample.

In the region D, CrOOH (passivation film) is already nonexistent on the Cr sample surface, and the metal Cr is in contact with the etching solution. As seen from the Pourbaix diagram of Cr, Cr²⁺ is stable at −700 mV, and thereby the metal Cr elutes according to the following expression (5).
Cr→Cr²⁺+2e⁻ (5)

At this time, the Cr sample functions as an anode as it discharges electrons from its surface to the etching solution, and the polarities of the regions B and C have reversed. The reversal of the current flowing direction at the time of the shift from the region C to the region D is attributed to the reversal of the polarities.

As specifically described above, coexistence and electrical short-circuit of Cr and Cu cause a decrease in Cr surface potential to facilitate elution of the passivation film on the Cr surface into the etching solution, thereby enabling stable and effective etching.

The diffusion step is carried out for “coexistence and electrical short-circuit of Cr and Cu”, to diffuse the second layer Cu in the third layer Cr (grain boundary) and on the surface thereof.

In the present invention, in the diffusion step, the second film Cu is diffused in the third layer Cr, the grain boundary of the third layer Cr to be more exact, or on the surface of the third layer Cr, so as to allow the passivation film of Cr to be easily removed by etching. The grain boundary of the third layer Cr is applied here because Cu does not form a solid solution with Cr in a thermodynamically equilibrium state, and preferentially diffuses to the surface by transmitting through the Cr grain boundary.

The diffusion of Cu as having transmitted through the Cr grain boundary is achieved by a process for applying a thermal energy to Cu mainly at the time of formation of the laminated films. In particular, the diffusion is achieved by keeping the substrate temperature at 150° C. or higher, and more preferably 200° C. or higher, for 2 to 15 minutes during a period from the time after the formation of the second layer Cu to the time immediately before the formation of the third layer Cr.

Further, in place of the above operation, the diffusion step may be carried out by keeping the atmospheric temperature of the laminated films at 150° C. or higher, and more preferably 200° C. or higher, for 2 to 15 minutes after the formation of the laminated films.

The diffusion step is desirably performed under reduced pressure close to vacuum or in a reducing atmosphere such as H₂, N₂ or Ar in order to prevent, to the utmost, further oxidation of the outermost surface of the third layer Cr due to the process atmosphere.

### EXAMPLE

In the following, an example is described.

A transparent electrode comprising an ITO film is formed on a glass substrate by sputtering. After patterning with use of a resist, etching is performed to form a transparent electrode. An aqueous solution of FeCl₃ at 40° C. is used as an etching solution, and etching is completed in about 200 seconds.

A first layer Cr and a second layer Cu are formed by sputtering on the glass substrate where the transparent electrode has been formed. After formation of the second layer Cu, the substrate is heated to a temperature of 150° C. or higher in the vacuum chamber, and then a third layer Cr is formed.

After patterning with use of the resist on the laminated films of Cr/Cu/Cr, the laminated films are etched in order from the surface. As the etching solution, an HCl aqueous solution at 40° C. is used for the third layer Cr, an FeCl3 aqueous solution at 40° C. for the second layer Cu, and an HCl aqueous solution at 40° C. for the first layer Cr.

Etching of the third layer Cr began simultaneously with soaking thereof in the etching solution, and etching was completed in about 60 seconds. The second layer Cu was etched for about 300 seconds and the first layer Cr was etched for about 60 seconds. The shape of the completed electrode of the laminated films was observed to find that the cross section of the second layer Cu matched that of the third layer Cr, and thus the third layer Cr did not overhang more than the second layer Cu in eaves shape, not forming a so-called “eaves shape”.

A dielectric material was formed on this electrode, and the dielectric glass covers the surface of the electrode without any void, thereby disconnection of a wire did not occur due to an arc current even when the panel was lighted.

The laminated films before formation of the dielectric layer were subjected to an auger electron spectroscopy (AES) analysis, simultaneously with sputtering with Ar⁺ from the surface side of the laminated films, to study a concentration distribution of Cu in the depth direction of the third layer Cr.

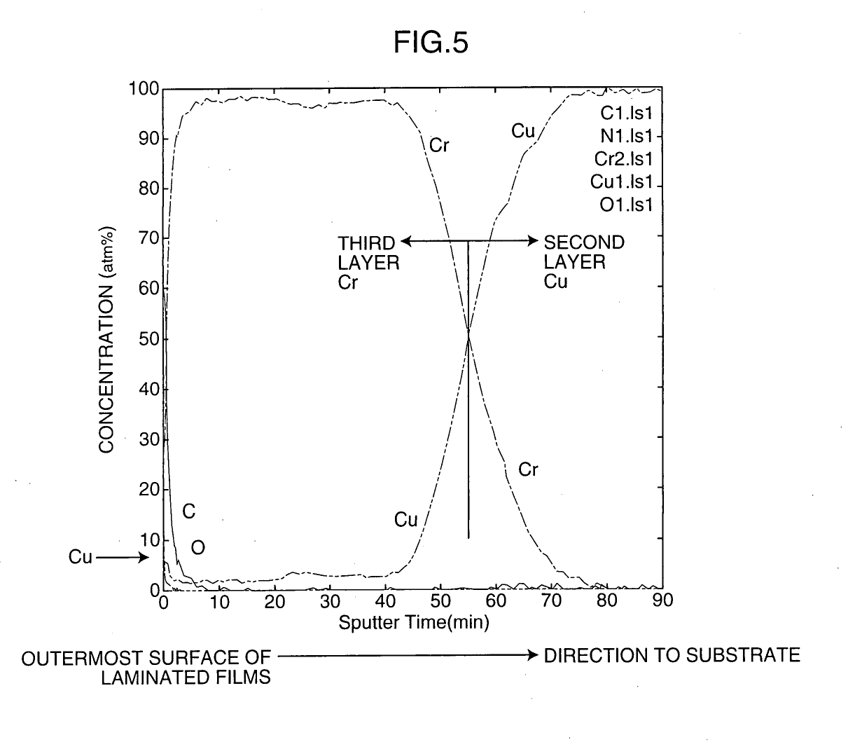

FIG. 5 shows a result of such a measurement as a graph showing the relation between the depth of the laminated films and the element concentration. As shown in this graph, it was confirmed as a result of the analysis of the laminated films that Cu existed in and on the surface of the third layer Cr. The concentration of Cu in the third layer Cr was from 1.7 to 3.3 atm%. Further, there were many impurities formed by an air element such as C or O on the surface of the third layer Cr (cf. Table 1). Therefore, assuming that those impurities were removed and only Cr and Cu constitute the layer, a calculation was made again, to estimate that 31.7 atom% of Cu existed on the surface of the third layer Cr.

TABLE 1
Element composition in the surface of the third layer Cr

Element

| | C | O | Cr | Cu |
|---|---|---|---|---|
| Existence ratio (atm %) | 23.5 | 51.3 | 16.6 | 7.7 |

In the present example, after formation of the second layer, the substrate was heated in the vacuum chamber until the substrate temperature is 150° C. or higher, and then the third layer Cr was formed. Instead, however, the substrate may be heated in the vacuum chamber until the substrate temperature is 150° C. or higher after the formation of the third layer Cr. Further, the same treatment may be performed not in the vacuum chamber, but in a reducing atmosphere, without any problem.

### COMPARATIVE EXAMPLE

The first layer Cr, the second layer Cu and the third layer Cr were formed by sputtering on the glass substrate. The diffusion step was not carried out during a period from the time after the formation of the second layer Cu to the time of the formation of the third layer Cr. The same processes were performed as in the above example except for the formation of the laminated films of Cr/Cu/Cr.

Etching of the third layer Cr began about 60 seconds after soaking thereof in the etching solution. It required 120 seconds, about twice as long as the time required in the above example, before the third layer Cr became completely nonexistent.

The shape of the completed electrode after etching of the second layer Cu and the first layer Cr was observed to find that the third layer Cr overhung more than the second layer Cu in eaves shape.

When a dielectric glass layer was formed on the electrode of the laminated films as thus formed, there were places where the dielectric glass layer was not covering the electrode, and disconnection of a wire occurred due to an arc current when the completed PDP was lighted.

The laminated films before formation of the dielectric material were subjected to the AES analysis to study the concentration distribution of Cu in the depth direction of the third layer Cr in the same manner as in the example.

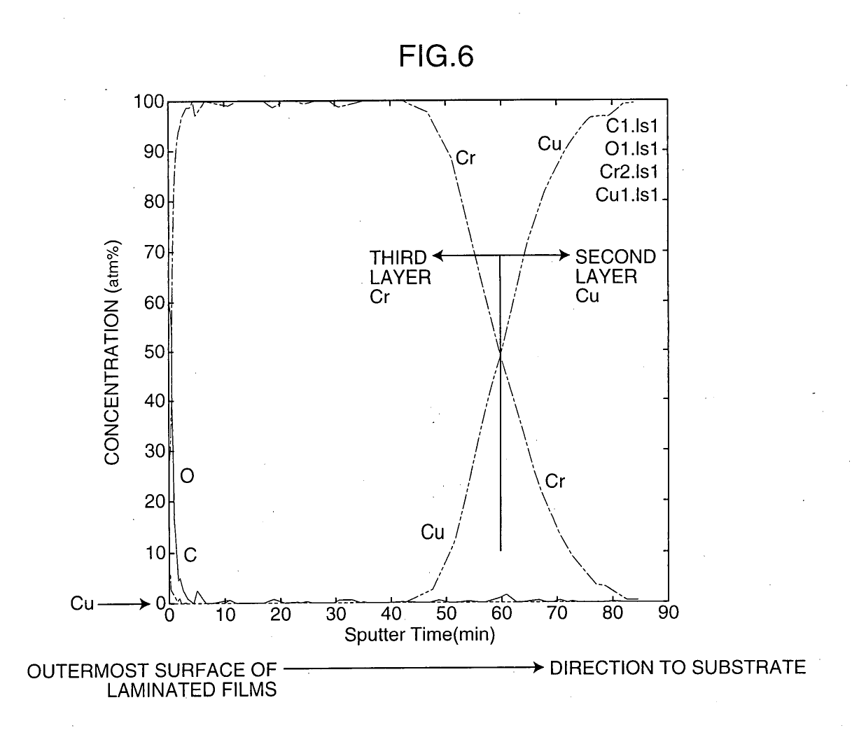

FIG. 6 shows a result of such a measurement as a graph showing the relation between the depth of the laminated films and the element concentration, as in FIG. 5. With the diffusion step not carried out in the comparative example, Cu was not detected in and on the surface of the third layer Cr.

As shown in this comparative example, according to the present invention, the second layer Cu is diffused in the third layer Cr, the grain boundary of the third layer Cr to be more exact, or on the surface of the third layer Cr to allow the Cr and Cu to be coexistent and electrically short-circuited so as to etch the third layer Cr in a stable and effective manner, while keeping the third layer Cr in proper shape. It is thereby possible to sufficiently fill the sides of the electrode with the dielectric glass to prevent electrode discontinuity due to an arc current, so as to provide an AC-type PDP having excellent display quality and reliability.

What is claimed is:

1. A method of forming an electrode for a plasma display panel having an electrode covered with a dielectric layer, the method comprising:
forming a first metal film on a second metal film after formation of at least the second metal film on a substrate;
forming a resist pattern for electrode formation on the top face of the laminated first and second metal films; and
etching the laminated first and second metal films with an etching solution, thereby forming an electrode of the laminated films,
wherein a first metal constituting the first metal film is different from a second metal constituting the second metal film, the first metal and the second metal having properties such that the surface potential of the first metal decreases when the first metal and the second metal in the state of being soaked in an etching solution of the first metal are short-circuited, and
during or after the formation of the first metal film, a diffusion step is performed in which an atmospheric temperature is kept at such a temperature that the metal atoms of the second metal film diffuse in and on the surface of the first metal film.

2. The method of claim 1, further comprising forming a third metal film under the second metal film before the formation of the second metal film,
wherein a third metal constituting the third metal film is the same metal as the first metal constituting the first metal film.

3. The method of claim 1, wherein the first metal comprises a metal selected from Cr, Ti, V, Ni, W and a group of alloys of these metals, and the second metal comprises a metal selected from Au, Ag, Cu, Al and a group of alloys of these metals.

4. The method of claim 1, wherein the second metal film and the first metal film are formed by vacuum processing.

5. The method of claim 1, wherein the atmospheric temperature in the diffusion step is 150° C. or higher.

6. The method of claim 1, wherein the diffusion step is carried out under reduced pressure.

7. The method of claim 1, wherein the diffusion step is carried out in a reducing atmosphere.

8. The method of claim 1, wherein the etching solution is an acidic aqueous solution.

9. The method of claim 1, wherein
the electrode of the laminated films has a three-layered structure of a first layer of Cr, a second layer of Cu and a third layer of Cr in order from the substrate side, and
the metal atoms of the second layer Cu are diffused in and on the surface of the third layer Cr in the diffusion step.

10. The method of claim 9, wherein the diffusion step comprises keeping the atmospheric temperature at such a temperature that the metal atoms of the second layer Cu diffuse in and on the surface of the third layer Cr during a period from completion of the formation of the second layer Cu to completion of the formation of the third layer Cr.

11. The method of claim 9, wherein the diffusion step comprises keeping the atmospheric temperature at such a temperature that the metal atoms of the second layer Cu diffuse in and on the surface of the third layer Cr for a prescribed period of time after the formation of the third layer Cr.
